(19) United States
(12) Patent Application Publication
(10) Pub. No.: US 2006/0258189 A1
(43) Pub. Date: Nov. 16, 2006

(54) Electrical connector

(75) Inventor: Wei Hua Pan, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/432,212

(22) Filed: May 10, 2006

(30) Foreign Application Priority Data
May 12, 2005 (CN) 200520071684.0

(51) Int. Cl. H05K 1/00

(52) U.S. Cl. 439/79

(57) ABSTRACT

An electrical connector comprises an insulative housing, front and rear channels in the insulative housing and a hollow space defined between the front and corresponding rear channel, a plurality of front and rear contacts received respectively in said front and rear channels, said hollow space defines at least one block for separating the front and the rear contacts from each other, and avoid the front and rear contacts contacting each other for assuring the stable transmission of the signal.

### BACKGROUND OF THE INVENTION

1. Field of the Invention

The present invention relates to electrical connectors and more particularly to electrical connectors used to interconnect electronic assemblies, for example, an ODD (Optical Disk Drive).

2. Description of the Related Art

In the field of the electronics, with the trend that electrical products are developing to smaller size, smaller and lighter electrical connectors used in the electrical products are needed and the contacts in the connectors are also required to be formed with smaller space between each other. However, high-density contacts assembly brings a new problem that how to prevent short circuit. For resolving the above problem, U.S. Pat. No. 6,024,603 discloses a connector, which has upper contacts and lower contacts. The upper contacts and lower contacts are staggerly mounted to a housing. A plurality of blocks are defined on the rear wall of the housing to separate the contacts from each other. But along the desire to transmit information at a faster rate and have a bigger capacity, the number of the contacts is increasing highly. The above-mentioned structure of the contacts assembly will take a large space of the housing along the horizontal direction. Thereby, an improving structure of contacts assembly is proposed, which puts the two lines of contacts respectively in the front and rear position of the housing. Please refer to U.S. Pat. No. 6,375,506, wherein the contacts are divided to two lines and each contact is positioned in a channel. The contacts in same line are separated from each other by a plurality of walls of the channels. The disadvantage of this means is that it doesn't have any block structure and when the rear contacts are mounted to the channels, they may touch the front contacts that have been mounted, especially a big force is put to the rear contacts.

Hence, an electrical connector is needed to overcome the foregoing shortcomings.

### BRIEF SUMMARY OF THE INVENTION

A main object of the present invention is to provide an electrical connector that can efficiently prevent short circuit.

An electrical connector comprises an insulative housing, front and rear channels in the insulative housing and a hollow space defined between each front and corresponding rear channel, a plurality of front and rear contacts received respectively in said front and rear channels, said hollow space defines at least one block for separating the front and the rear contacts from each other.

Other objects, advantages and novel features of the present invention will become more apparent from the following detailed description of the present embodiment when taken in conjunction with the accompanying drawings.

### BRIEF DESCRIPTION OF THE DRAWINGS

FIG. 1 is a perspective view of the electrical connector according to the present invention.

FIG. 2 is an exploded view of the electrical connector according to the present invention.

FIG. 3 is another perspective view of the electrical connector according to the present invention.

FIG. 4 is a cross-sectional view taken along a line 4-4 in FIG. 1 according to the present invention.

FIG. 5 is a sectional view according to the present invention.

### DETAILED DESCRIPTION OF THE INVENTION

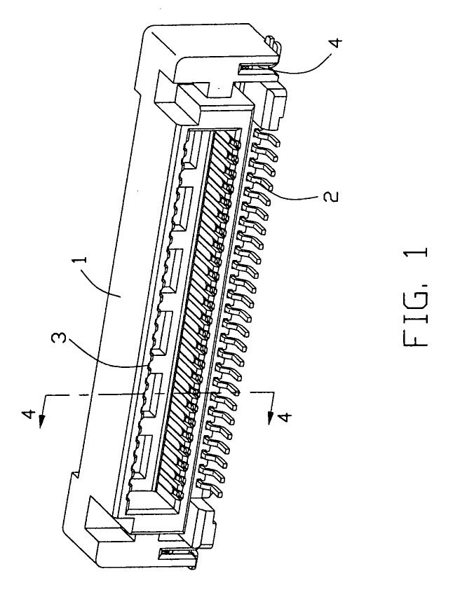

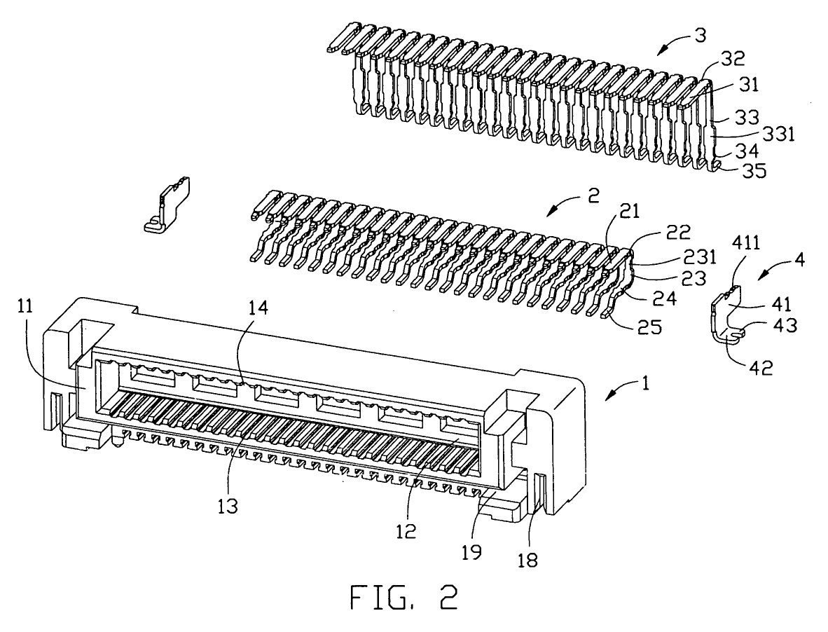

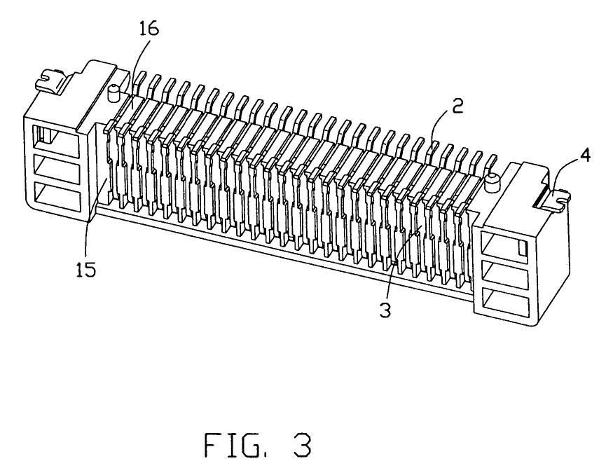

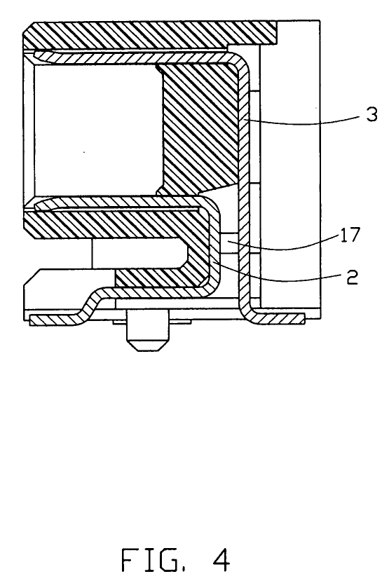

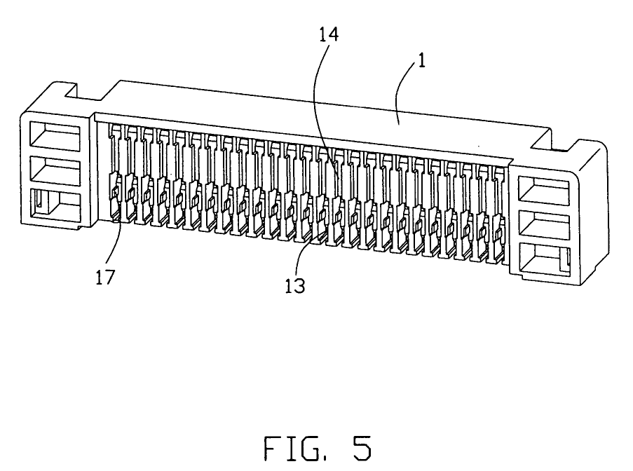

Referring to FIGS. 1 to 5, the electrical connector of the present invention comprises an insulative housing 1, a plurality of front contacts 2 and rear contacts 3 receiving in the housing and soldering pads 4 retained on opposite ends of the insulative housing.

The insulative housing 1 is made of insulative plastic and has a longitude structure. An interface 11 in the front of the housing is provided, which defines a receiving space 12 for receiving a contacting board of a mating connector (not labeled). The insulative housing comprises front and rear receiving channels 13, 14, wherein front contacts 2 and rear contacts 3 are received and a hollow space (not labeled) is defined between each front contact 2 and corresponding rear contact 3. Further a block 17 is projecting from one of the sidewalls of the hollow space. The rear channels 14 extend along the top inner surface (not labeled) of the receiving space 12 toward to and through the rear wall 15 of the housing 1, and then extend vertically along the rear wall 15 toward to and through the bottom wall 16 of the housing 1. The front channels 13 extend along the bottom inner surface (not labeled) of the receiving space 12 to the block 17 but not beyond and then extend downwardly and through the bottom wall 16 of the housing 1. Further more, a pair of retaining grooves 18 are formed at the ends of the housing 1 and a longitude slot 19 is defined between the receiving space 12 and the bottom wall 16, for receiving the sidewall of the mating connector.

The front contacts 2 and the rear contacts 3 are made of metal, and are respectively received in the front channels 13 and rear channels 14. The front contacts 2 are formed with a U shape and the rear contacts 3 are formed with a L shape. Each front contacts 2 and the rear contacts 3 respectively comprises a contacting portion 21, 31 retaining respectively in the top and bottom inner surface of receiving space 12, a first retaining portion 22, 32 extending backwardly from the contacting portion 21, 31, a vertical connecting portion 23, 33 bending downwardly from the first retaining portion 22, 32, a second retaining portion 24, 34 and a tail portion 25, 35. Wherein, the second retaining portion 24 and the vertical connecting portion 23 of the front contacts 2 are perpendicular to each other and the second retaining portion 34 of the rear contacts 3 is extending downwardly from the vertical connecting portion 33. The vertical connecting portion 23 of the front contacts 2 is formed with a narrow portion 231 concave insideward and the vertical connecting portion 33 of the rear contacts 3 is formed with a wide portion 331 extending outward. The front contacts 2 and the rear contacts 3 are mounted to the housing 1 forwardly from the rear wall 15 of the housing 1. The width of the narrow portion 231 of the front contacts 2 is smaller than the width of hollow space where the block 17 is formed and the front contacts 2 can pass the blocks 17 and get into the channels 13. Oppositely, the width of the wide portion 331 of the rear contacts 3 is bigger than the width of hollow space where the block 17 is formed and therefor the rear contacts 3 can't pass the block 17 and keep retaining in the rear channels 14. By this, each front contact 2 and corresponding rear contact 3 are separated from each other efficiently by the block 17 between them, even if a big force is put to the rear contact 3 when mounted to the housing. Therefor it can prevent the short circuit of the contacts by the block 17 formed between the front and rear channels 13, 14. The front and rear contacts 2, 3 are retained in the housing firmly by the interference between the first and second retaining portion 22, 24, 32, 34 and the front and rear channels 13, 14.

A pair of soldering pads 4 are formed with an L shape, and are received in the retaining grooves 18 at the ends of the housing 1. The soldering pad 4 comprises vertical portion 41 and horizontal portion 42. The vertical portion 41 is formed with a retaining portion 411 on the top of the rear end of the vertical portion 41 and the soldering pad 4 is retained in the housing 1 firmly by the interference between said retaining portion 411 and the retaining groove 18. The horizontal portion 42 defines a soldering hole for enhance the soldering intensity.

Obviously, the electrical connector of the present invention has other embodiments, for example, the hollow space can be formed with two blocks respectively on the two sidewalls of the hollow space and opposite to each other and thereby the connecting portion of the contact is configured with concave structure on one side or on two sides according to the number of the blocks formed in the hollow space.

It is to be understood, however, that even though numerous, characteristics and advantages of the present invention have been set fourth in the foregoing description, together with details of the structure and function of the invention, the disclosed is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical connector comprising:
an insulative housing;
front and rear channels formed in said insulative housing and hollow spaces defined between each front and corresponding rear channels;
a plurality of front and rear contacts mounted to the insulative housing forwardly from the rear wall of the insulative housing and received in said front and rear channels respectively;
said hollow space defining at least one block permitting the front contact to pass through and block off the rear contact to separate the front contact and corresponding rear contact from each other.

2. The electrical connector according to claim 1, wherein each of the front and rear contacts have a contacting portion, a connecting portion and a tail portion, the connecting portions of the front contact and the rear contact are formed respectively with a narrow portion and a wide portion.

3. The electrical connector according to claim 2, wherein the width of the narrow portion of the front contact and the width of the wide portion of the rear contact are respectively smaller and bigger than the hollow space where said block is formed.

4. The electrical connector according to claim 2, wherein the front contacts and the rear contacts are respectively formed with a U shape and a L shape.

5. The electrical connector according to claim 1, wherein said insulative housing comprises a rear wall, a bottom wall and further a receiving space defining a top and a bottom inner surface, wherein the rear channel extends along the top surface toward to and through the rear wall of the housing, and then extends from the rear wall to and through the bottom wall of the housing, and the front contact extends along the bottom inner surface to the block but not beyond and then extends downwardly to and through the bottom wall of the housing.

6. The electrical connector according to claim 2, wherein each front contact comprises a connecting portion, a pair of retaining portions perpendicular to the connecting portion and each rear contact comprises a connecting portion, a pair of retaining portions respectively perpendicular to and extending downward from the connecting portion.

7. The electrical connector according to claim 1, further comprising a pair of soldering pads each received in the insulative housing, each soldering pad comprises a vertical portion and a horizontal portion, wherein the vertical portion is formed with a retaining portion on the top of the rear end of the vertical portion and the horizontal portion defines a soldering hole.

8. The electrical connector according to claim 7, wherein the insulative housing comprises a pair of retaining grooves at the ends of the housing for receiving said soldering pads.

9. An electrical connector comprising:
an insulative housing defining a plurality of passageways extending in a front-to-back direction;
a plurality of terminals forwardly assembled to the housing from a rear face of the housing, respectively, each of said terminals defining a front contacting portion extending into the corresponding passageway, a rear soldering portion exposed outside of the housing, and a vertical connecting portion connected between said soldering portion and said contacting portion; and
two of said terminals neighboring with each other and having connecting portions aligned with each other in said front-to-back direction; wherein
one of said two neighboring terminals, which has the connecting portion in front of that of the other and is assembled to the housing prior to the other, defines a narrowed region around the corresponding connecting portion so as to escape, during forward assembling, from a projecting structure formed around said rear face of the housing, while the other lacks said narrowed region on the corresponding connecting portion and inevitably abuts against said projecting structure so as to be efficiently spaced from the connecting portion of said one of the two neighboring terminals in said front-to-back direction.

10. The connector as claimed in claim 9, wherein said one of the two neighboring terminals is located at a lower level while the other of said two neighboring terminals is located at an upper level.

11. The connector as claimed in claim 9, wherein the two passageways respectively receiving said two neighboring terminals, are aligned with each other in a vertical direction.

12. An electrical connector comprising:
an insulative housing defining a plurality of passageways extending in a front-to-back direction;
a plurality of terminals forwardly assembled to the housing from a rear face of the housing, respectively, each of said terminals defining a contacting portion extending into the corresponding passageway, a soldering portion exposed outside of the housing, and a vertical connecting portion connected between said soldering portion and said contacting portion; and
two of said terminals neighboring with each other and having connecting portions aligned with each other in said front-to-back direction; wherein
one of said two neighboring terminals, which has the connecting portion in front of that of the other and is assembled to the housing prior to the other, defines a region around the corresponding connecting portion so as to pass through, during forward assembling, a corresponding connecting portion slot formed around said rear face of the housing, while the other defines a wider portion on the corresponding connecting portion relative to that of said one, and inevitably abuts against the rear face of the housing and is prohibited from entering the said corresponding connecting slot so as to be efficiently spaced from the connecting portion of said one of the two neighboring terminals in said front-to-back direction.

13. The connector as claimed in claim 12, wherein said one of the two neighboring terminals is located at a lower level while the other of said two neighboring terminals is located at an upper level.

14. The connector as claimed in claim 12, wherein the two passageways respectively receiving said two neighboring terminals, are aligned with each other in a vertical direction.
